(19) United States
(12) Patent Application Publication
(10) Pub. No.: US 2006/0068546 A1
(43) Pub. Date: Mar. 30, 2006

(54) Self-aligned non-volatile memory and method of forming the same

(76) Inventor: Yi-Shing Chang, Hsinchu City (TW)

Correspondence Address: BIRCH STEWART KOLASCH & BIRCH, PO BOX 747, FALLS CHURCH, VA, 22040-0747, US

(21) Appl. No.: 10/951,688

(22) Filed: Sep. 29, 2004

(51) Int. Cl. H01L 21/336

(52) U.S. Cl. 438/257

(57) ABSTRACT

A non-volatile memory is described. A substrate comprising a stacked layer is provided. A sacrificial layer is deposited and patterned to form a first opening. A first spacer is formed on sidewalls of the first opening, and the stacked layer is etched using the first spacer as a first mask to form a second opening. An isolation layer is formed in a portion of the first and the second openings, and a conductive filling layer is formed thereon. The stacked layer is etched using a portion of the conductive filling layer as a second mask.

### BACKGROUND OF THE INVENTION

1. Field of the Invention

The invention relates to a method for fabricating a semiconductor device, and more particularly to a method for fabricating a split gate flash memory and a split gate flash structure made thereby.

2. Description of the Related Art

A non-volatile memory, such as flash memory, retains data regardless of electrical power supplied, and reads and writes data by controlling a threshold voltage of a control gate.

FIG. 1 illustrates a cross-sectional view of a conventional flash electrically erasable and programmable read only memory (EEPROM) cell. A plurality of floating gates 104 with gate dielectrics 102 underneath are formed on a substrate 100 by lithography, as shown in FIG. 1. An insulating layer 114 is conformally formed on the substrate 100 and the floating gates 104. A control gate layer 116 and a dielectric layer 118 are subsequently formed thereon. Another lithography process is next performed with a photo mask 120 formed on the dielectric layer 120. Thereafter, a control gate defined by the photo mask 120 is formed between the floating gates 104 (as marked within dotted lines).

To fabricate such flash EEPROM cell, however, two photo lithography processes are essentially used for formation of the floating gates 104 and the control gate, respectively. As a result, the manufacturing process of the memory cell becomes complicated and costs lots.

Moreover, the floating gates 104 suffer different channel lengths 106A and 106B owing to misalignment during lithography processes. That is, the widths of the floating gates 104 are inconsistent. Therefore, the reliability of the resultant flash is reduced.

### SUMMARY OF THE INVENTION

Accordingly, an object of the invention is to provide a fabrication method and split gate flash structure with a floating gate channel length defined by self-alignment method, to produce a consistent floating gate channel length and select gate channel length.

It is another object of the invention to provide a method of forming a spilt gate flash memory, which is performed more easily and leads to lower cost.

To achieve the above objects, one aspect of the present invention provides a self-aligned non-volatile memory. Two isolated storage blocks of the same width are disposed over a substrate. A gate is disposed over the substrate and between the two storage blocks, wherein the width of each storage block is defined by a spacer thereon.

Another aspect of the present invention provides a self-aligned split gate flash fabricating method. A substrate comprising a stacked layer is provided. A sacrificial layer is deposited and patterned to form a first opening. A first spacer is formed on a sidewall of the first opening, and the stacked layer is etched using the first spacer as a first mask to form a second opening. An isolation layer is formed in a portion of the first and the second openings, and a conductive filling layer is formed thereon. The stacked layer is etched using a portion of the conductive filling layer as a second mask.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross section of a conventional split gate flash;

FIGS. 2A-2H illustrate process steps for fabricating a split gate flash of the first embodiment;

FIG. 2I is a top view of a split gate flash of the invention;

FIG. 2J is a cross section along line 2J-2J′ of FIG. 2I;

FIGS. 3A-3F illustrate process steps for fabricating a split gate flash of the second embodiment; and

FIGS. 4A-4E illustrate process steps for fabricating a split gate flash of the third embodiment.

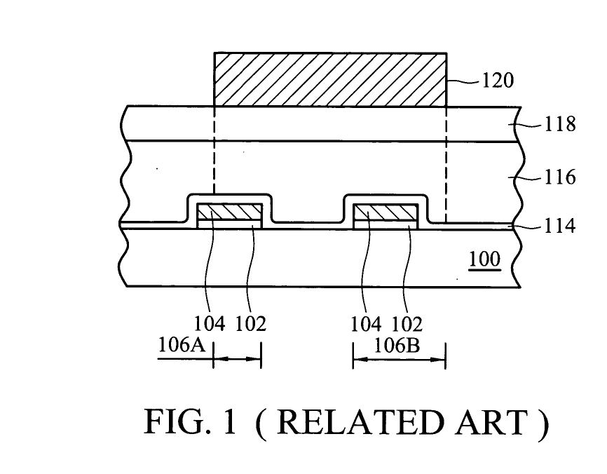

### DETAILED DESCRIPTION OF THE INVENTION

Three preferred embodiments are disclosed. The first embodiment discloses a flash memory with a floating gate (storage block), a control gate and a select gate. The second embodiment discloses a flash memory with the floating gate (storage block) and the control gate. The third embodiment comprises a stack structure of a first silicon oxide layer, a silicon nitride layer (storage block) and a second silicon oxide layer. The channel length of the storage block common to the described embodiments is defined by a spacer thereon.

### First Embodiment

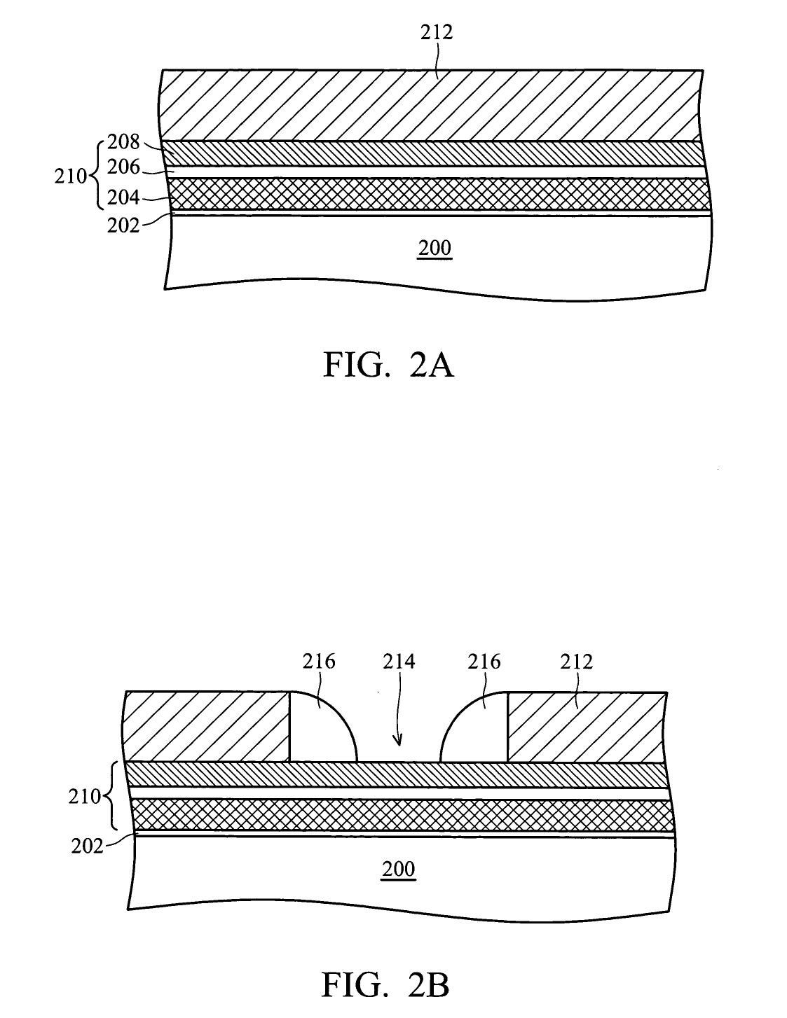

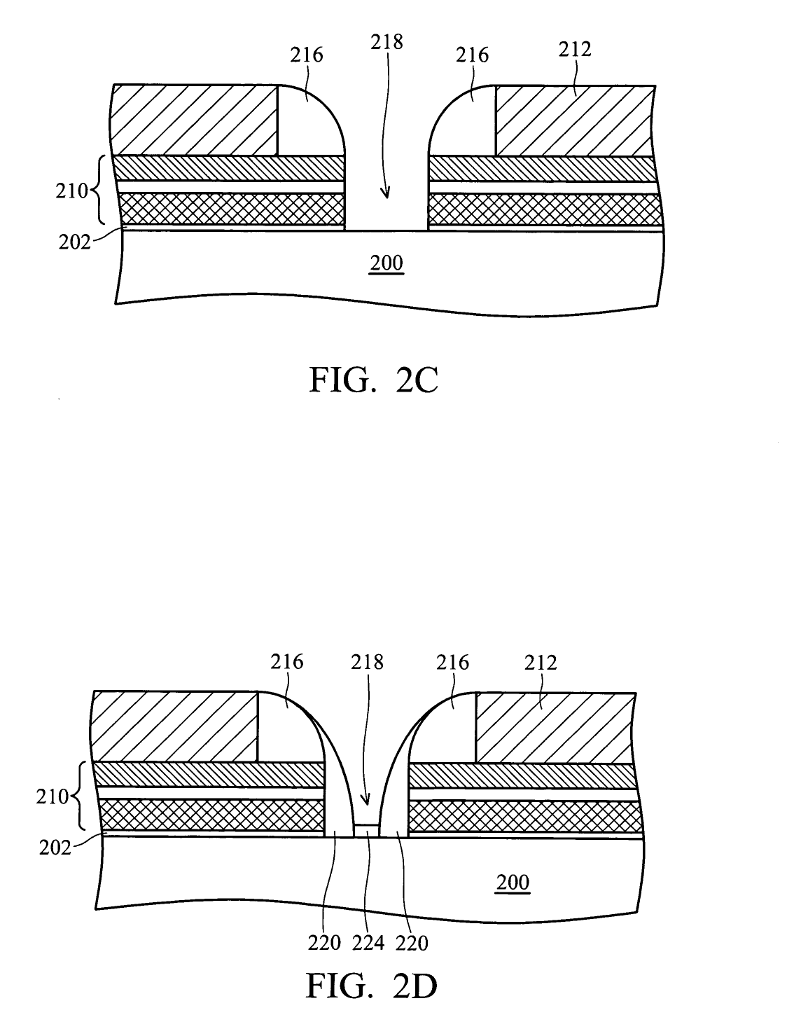

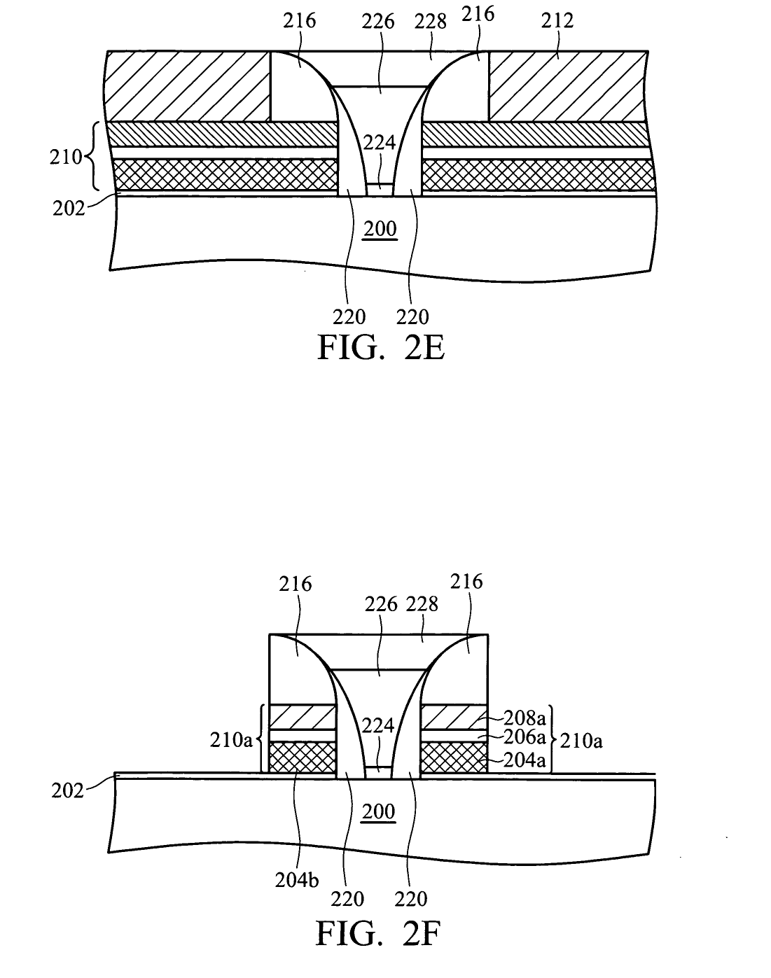

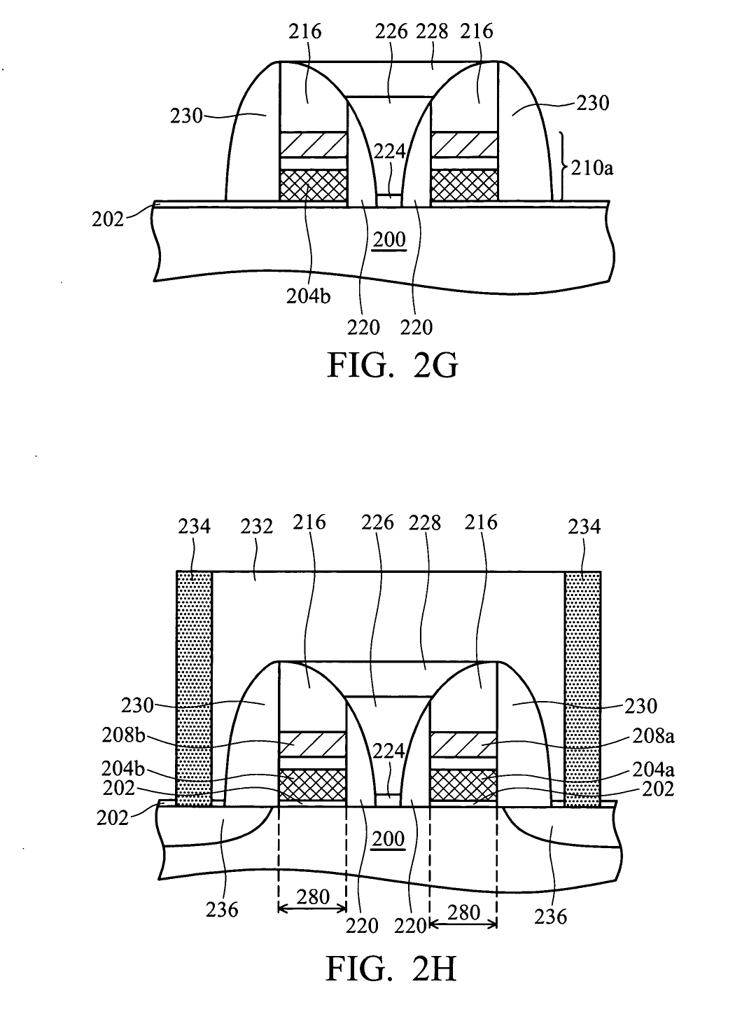

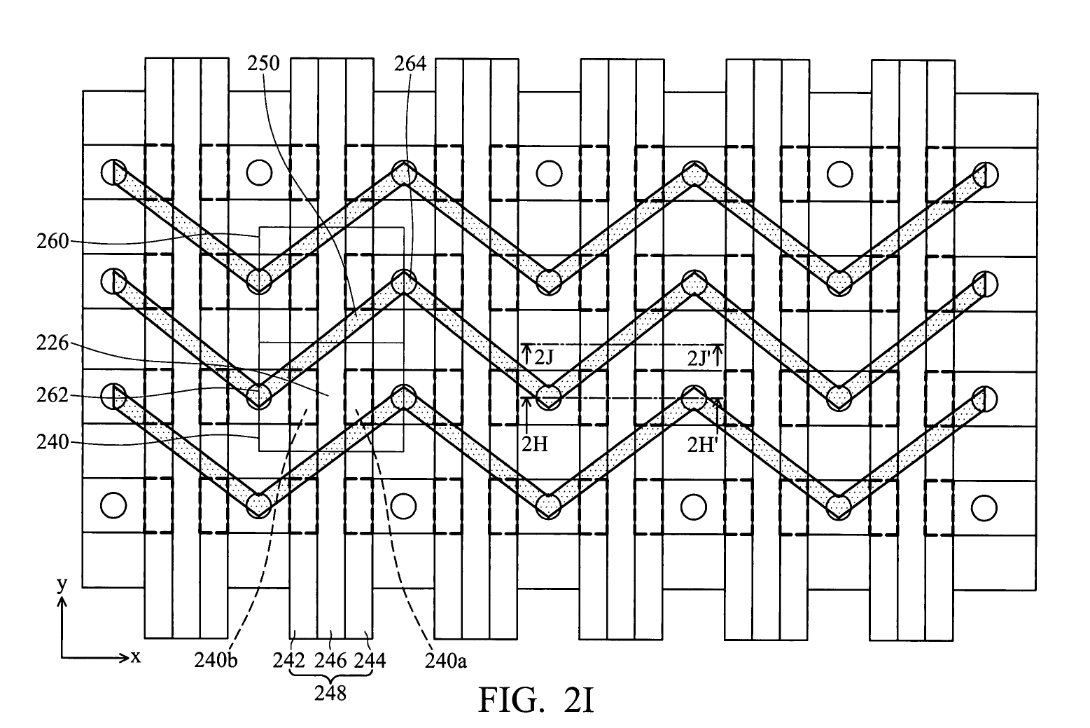

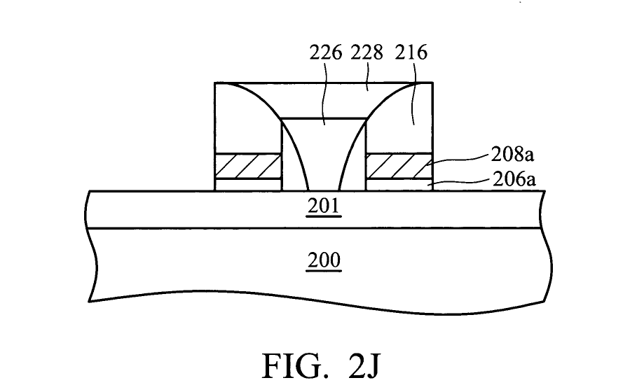

As shown in FIG. 2A, a substrate 200, preferably a silicon substrate, is provided, and a tunneling dielectric layer 202, preferably a silicon oxide layer, is formed thereon. A stacked layer 210 is formed on the tunneling dielectric layer 202. In this embodiment, the stacked layer 210 is a stacked film comprising a charge trapping layer 204, an inter dielectric layer 206, and a control gate layer 208. The charge trapping layer 204 and the control gate layer 208 may be polysilicon, and the inter dielectric layer 206 is an ONO film (a stacked film comprising a first silicon oxide layer, a silicon nitride layer, and a second silicon oxide layer). Further, a SONOS structure may be employed, for example, the charge trapping layer 204 is a silicon nitride layer, the control gate layer 208 is polysilicon, and the inter dielectric layer 206 is an oxide layer. A sacrificial layer 212, preferably comprising silicon nitride, is formed on the stacked layer 210.

As shown in FIG. 2B, the sacrificial layer 212 is patterned by a conventional lithography and etching method to form a first opening 214. A first dielectric layer (not shown) is deposited and etched back to form two first spacers 216 on sidewalls of the first opening 214. Preferably, the first dielectric layer (not shown) is silicon oxide and etched by anisotropic etching.

Referring to FIG. 2C, the stacked layer 210 is etched anisotropically using the first spacers 216 and the sacrificial layer 212 as a first mask to form a second opening 218. As shown in FIG. 2D, a second dielectric layer(not shown), preferably formed of silicon oxide, is deposited and etched back anisotropically to form a second spacer 220 on a sidewall of the second opening 218. The exposed substrate 200 is thermally oxidized to form a select gate dielectric layer 224 in the second opening 218.

Referring to FIG. 2E, a conductive filling layer 226, preferably comprising polysilicon, is deposited on the sacrificial layer 212 and fills the first and the second openings. The conductive filling layer 226 is retained a portion by, for example, polishing through chemical mechanical polishing process, or by etching back to remove the portion of the conductive filling layer 226 on the sacrificial layer 212. The conductive filling layer 226 is oxidized by thermal oxidization to form a mask layer 228 for providing adequate resistance during subsequent etching.

As shown in FIG. 2F, the sacrificial layer 212 and the stacked layer 210 are etched anisotropically in sequence using the mask layer 228 and the first spacers 216 as a second mask. Consequently, the etched stacked layer 210a comprises a floating gate 204a (also regarded as a storage block hereinafter), an inter dielectric layer 206a and a control gate 208a, and the conductive filling layer 226 is a select gate.

Due to the storage block 204a (floating gate) being defined by the first spacers 216 thereon, width and floating gate channel length thereof is consistent. Further, the pair storage blocks 204a and 204b defined by the first spacers 216 instead of conventional lithography processes have substantially the same width. The reliability of the resultant device is thus enhanced. Besides, a select gate with consistent channel length is formed easily since the select gate is formed between floating gates having consistent channel length. Moreover, the structure of FIG. 2F is formed by a self-aligned method and the second mask of the first spacers 216 and the mask layer 228. Consequently, another conventional photolithography process is unnecessary, that decreases the manufacturing cost and simplifies the manufacturing processes.

As shown in FIG. 2G, a third spacer 230 is formed on a sidewall of the patterned stacked layer 210a and the first spacer 216. In FIG. 2H, an inter-layer dielectric layer 232 is deposited blanketly over the substrate 200. Contact plugs 234 are formed in the inter-layer dielectric layer 232 to connect source/drain regions 236 in the substrate 200.

FIG. 2I is a top view of a self-aligned flash of the invention. FIG. 2H is a cross section along line 2H-2H′ of FIG. 2I. In FIG. 2H, two storage blocks 204a and 204b with the same width are disposed over a substrate 200, and a tunneling dielectric layer 202 is interposed therebetween. The substrate 200 and the storage blocks 204a and 204b are isolated with each other. A select gate (the conductive filling layer 226) is on the substrate 200 and between the two storage blocks 204a and 204b. The two storage blocks 204a and 204b are defined by two nearby spacers 216 to have the same width 280.

Because the select gate is disposed over the substrate 200 and shared by two floating gates 204a and 204b, the structure of memory cell shown in FIG. 2H is more compact. Hence, the size of the memory cell is effectively reduced.

FIG. 2J is a cross section along line 2J-2J′ of FIG. 2I. The inter dielectric layers 206a and the control gates 208a are on a STI region 201 of the substrate 200, and the select gate (the conductive filling layer 226) is interposed therebetween. A first spacer 216 is disposed on each control gate 208a, and a mask layer 228 is on the select gate 226.

Referring to FIG. 2I, the*self-aligned non-volatile memory comprises a plurality of parallel gate lines 248, bit lines 250 and pair cells 240. Each gate line 248 extends in a direction Y and two parallel control gate lines 242 and 244 are disposed on opposite sides thereof.

Each pair cell 240 comprises a gate electrode coupled to a corresponding gate line 246. Two control gates coupled to the corresponding control gate lines 242 and 244 are disposed on opposites sides thereof. Two storage blocks 240a and 240b (floating gates) are respectively located at opposing sides of the gate electrode. The storage blocks 240a and 240b are floating gates, and first and second contacts 262 and 264 are adjacent to the two storage blocks 240a and 240b, respectively.

First and second pair cells 240 and 260 are controlled by one of the gate lines 248 and neighboring to each other. One of the bit lines 250 connects the first contact 262 of the first pair cell 240 and the second contact 264 of the second pair cell 260. If the bit line 250 is perpendicular to the gate lines 248, the cells on the same row do not have a potential drop. Accordingly, as shown in FIG. 2I, most preferably the bit lines 250 extending substantially along direction X are disposed in a zigzag pattern and are isolated from each other. Furthermore, bit lines may be arranged to connect contacts of distant pair cells, as long as a potential drop occurs.

The program, erase, and read voltages employed for operating the memory cell of FIG. 2H with polysilicon as floating gates and an ONO film as an inter dielectric layer are listed in Table 1, where FG1 and FG2 represent the floating gates 204a and 204b, respectively, Vsg is the applied voltage of the select gate 226, Vs and Vd separately are the applied voltages of the source/drain regions 236, and Vcg1 and Vcg2 stand for the applied voltages of the control gates 208a and 208b, respectively. Thus, operation of the self-aligned flash is controlled in this way.

TABLE 1
Memory cell operation

| | | |
|---|---|---|
| Program | Erase | Read |

| | FG1 | FG2 | FG1 | FG2 | FG1 | FG2 |
|---|---|---|---|---|---|---|
| Vsg | 5 | 5 | 0 | 0 | 5 | 5 |
| Vs | 2 | 0 | 5 | 0 | 0 | 2 |
| Vd | 0 | 2 | 0 | 5 | 2 | 0 |
| Vcg1 | 8 | 2 | −5 | 0 | 0 | 2 |
| Vcg2 | 2 | 8 | 0 | −5 | 2 | 0 |

### Second Embodiment

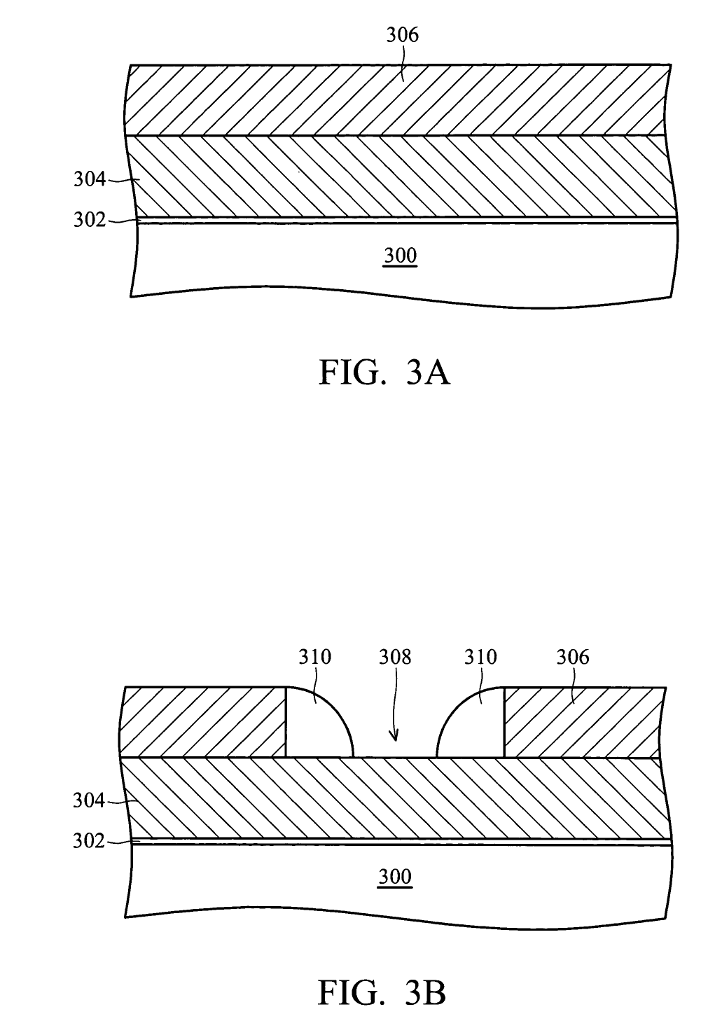

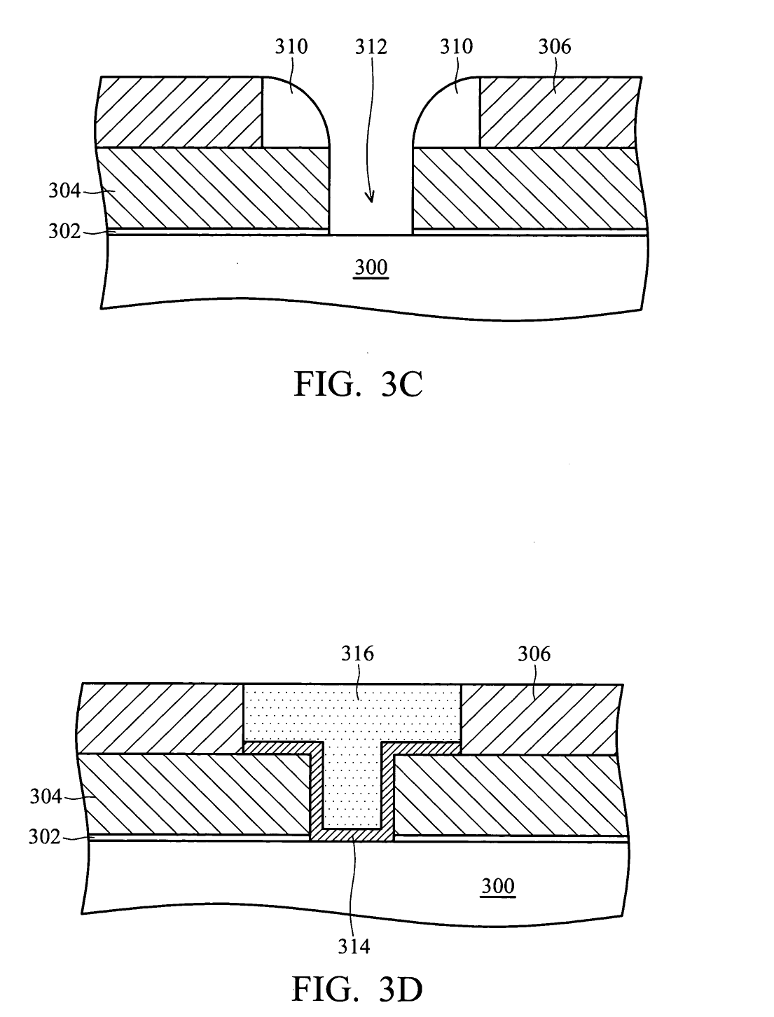

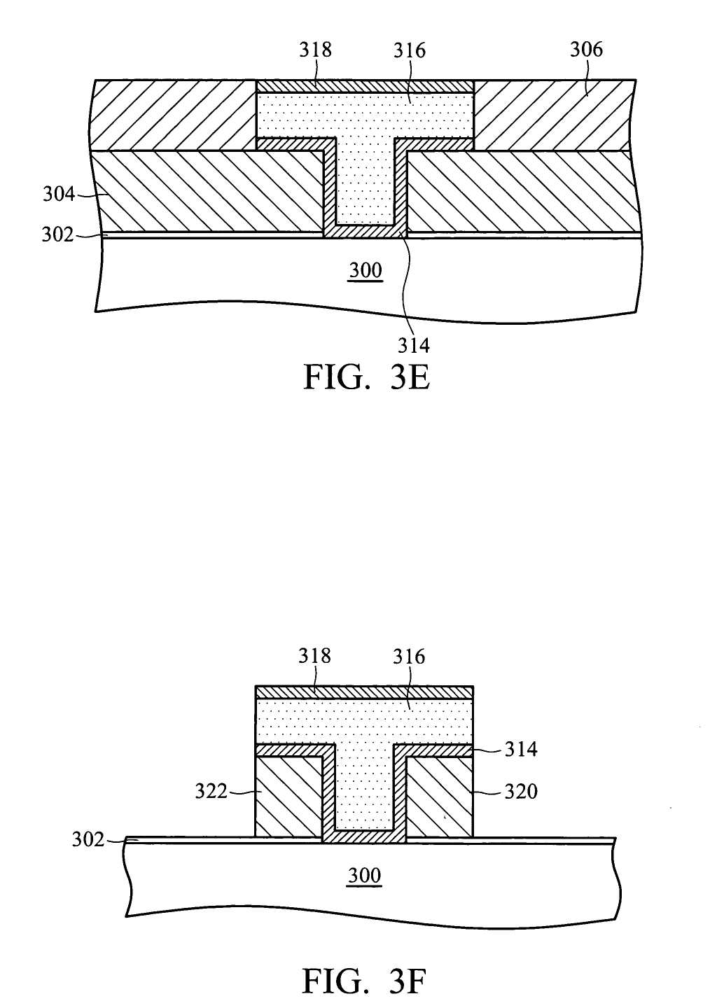

As shown in FIG. 3A, a substrate 300, preferably a silicon substrate, is provided, and a tunneling dielectric layer 302, preferably a silicon oxide layer, is formed thereon. A floating gate layer 304, preferably a polysilicon layer, is formed on the tunneling dielectric layer 302. A sacrificial layer 306, preferably formed of silicon nitride, is formed on the floating gate layer 304.

As shown in FIG. 3B, the sacrificial layer 306 is patterned by a conventional lithography and etching method to form a first opening 308. A first dielectric layer (not shown) is deposited and etched back to form two first spacers 310 on sidewalls of the first opening 308. Preferably, the first dielectric layer is silicon oxide and etched by anisotropic etching.

Referring to FIG. 3C, the floating gate layer 304 is anisotropically etched using the first spacers 310 as a first mask to form a second opening 312. As shown in FIG. 3D, the anterior first spacer 310 is removed, and the exposed substrate 300 and the floating gate layer 304 in the first and second openings 308 and 312 are oxidized to form an insulating layer 314 preferably comprising silicon oxide. In another embodiment, the first spacers 310 are remained, and the exposed substrate 300 and the floating gate 304 in the second opening 312 are oxidized to form an insulating layer.

Referring to FIG. 3D, a conductive filling layer 316, preferably comprising polysilicon, is deposited on the sacrificial layer 306 and fills the first and second openings. The conductive filling layer 316 is retained, for example, by polishing via a chemical mechanical polishing process, or by etching back the conductive filling layer 316 on the sacrificial layer 306. As shown in FIG. 3E, the conductive filling layer 316 is thermally oxidized to form a mask layer 318 for providing adequate resistance during subsequent etching.

As shown in FIG. 3F, the aforesaid sacrificial layer 306 and the floating gate layer 304 are etched anisotropically in sequence using the mask layer 318 as a second mask. Consequently, the etched floating gate layer 304 is transformed into two floating gates 320 and 322, and the conductive filling layer 316 serves as a control gate and a select gate.

Subsequent steps are also performed. For example, a third spacer is formed on a sidewall of the patterned stacked layer comprising the floating gate 320 and the conductive filling layer 316. An inter-layer dielectric layer is blanketly deposited over the substrate 300. Contact plugs are formed in the inter-layer dielectric layer to connect source/drain regions in the substrate 300.

Due to the storage blocks (floating gates 320 and 322) being defined by the forenamed first spacers 310 thereon, a consistent width and floating gate channel length is achieved. Further, the pair storage blocks 320 and 322 defined by the first spacers 310 instead of conventional lithography processes have substantially the same width. Absence of one lithography process also reduces manufacturing cost.

The operating method of program, erase, and read for the memory cell of the embodiment is a known art, and hence details thereof are not described herein.

### Third Embodiment

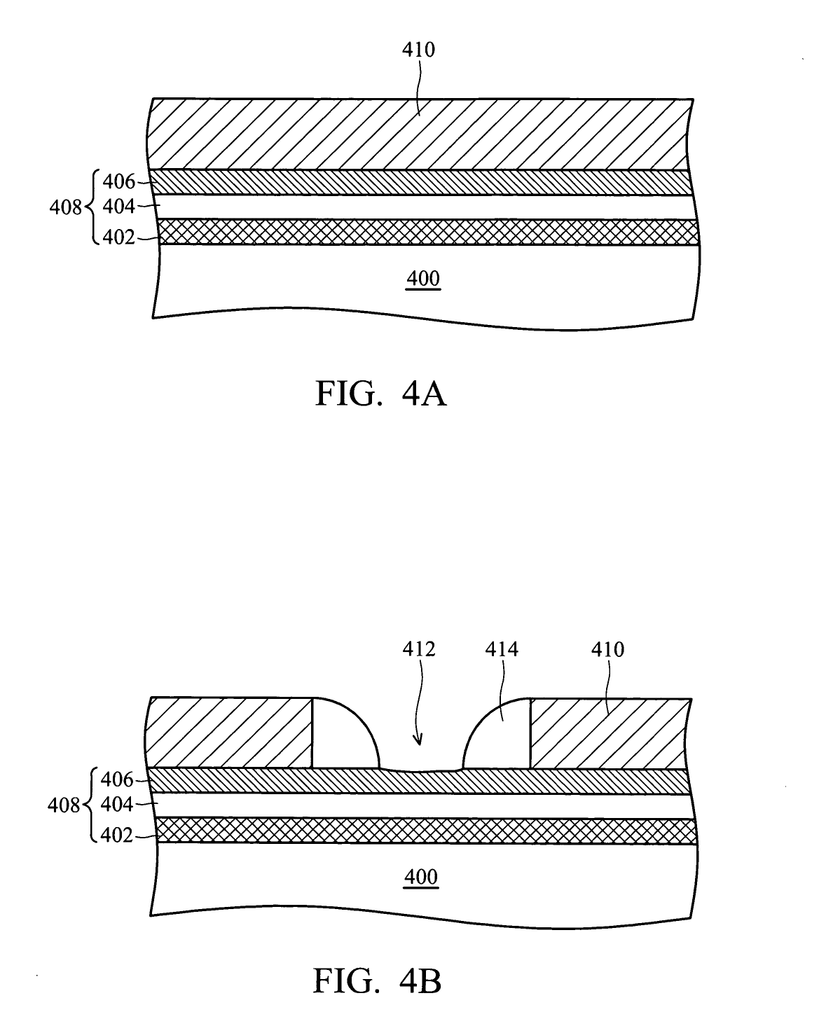

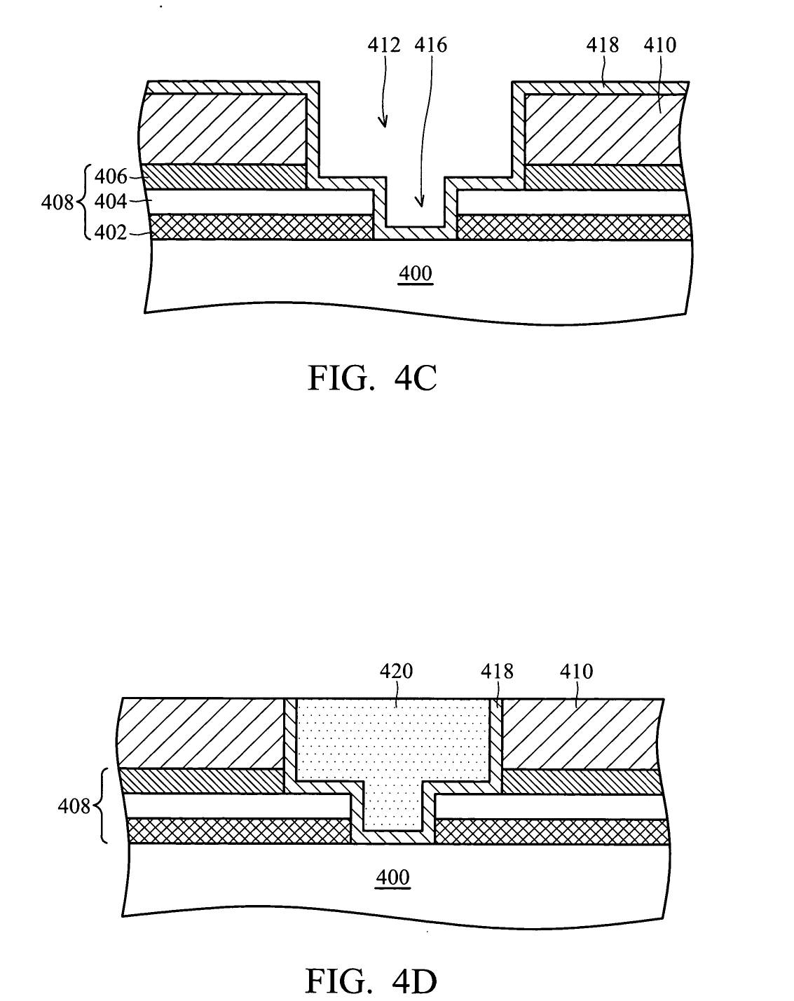

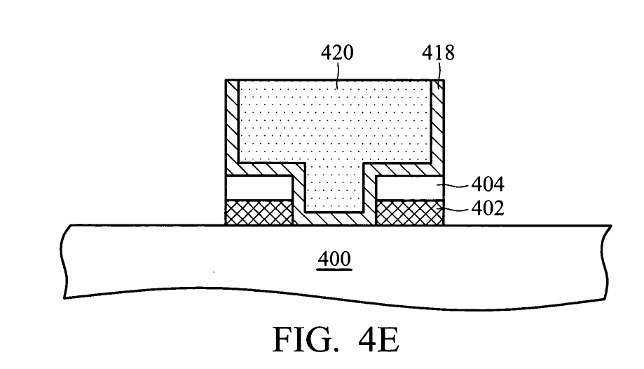

As shown in FIG. 4A, a substrate 400, preferably a silicon substrate, is provided, and a stacked layer 408 is formed thereon. In this embodiment, the stacked layer 408 is a stack film of a first oxide layer 402, a nitride layer 404, and a second oxide layer 406. A sacrificial layer 410, preferably comprising silicon nitride, is formed on the stacked layer 408

As shown in FIG. 4B, the sacrificial layer 410 is patterned by a conventional lithography and etching method to form a first opening 412. A first dielectric layer (not shown) is deposited and etched back to form two first spacers 414 on sidewalls of the first opening 412. Preferably, the first dielectric layer comprises silicon oxide and etched by anisotropic etching.

Referring to FIG. 4C, the stacked layer 408 is anisotropically etched using the first spacers 414 as a first mask to form a second opening 416. The aforementioned first spacers 414 and the second oxide layer 406 in the first and second openings 412 and 416 are removed by isotropic etching, for example, dipping HF. An isolation layer 418, preferably comprising silicon oxide, is deposited conformally on the sacrificial layer 410 and in the first and second openings 412 and 416.

Referring to FIG. 4D, a conductive filling layer 420, preferably comprising polysilicon, is deposited on the sacrificial layer 410 and fills the first and second openings 412 and 416. The conductive filling layer 420 is, for example, polished by chemical mechanical polishing or etched back thereof, remaining the portion in the first and second openings 412 and 416.

As shown in FIG. 4E, the anterior sacrificial layer 410, the isolation layer 418, the silicon nitride layer 404, and the first silicon oxide layer 402 are anisotropically etched in sequence using the conductive filling layer 420 as a second mask. Consequently, the etched silicon nitride layer 404 serves as a storage block, and the conductive filling layer 420 serves as a control gate and a select gate.

A third spacer is formed on a sidewall of the patterned stacked layer of the first silicon oxide layer 402 and the silicon nitride layer 404, and on a sidewall of the isolation layer 418. An inter-layer dielectric layer is further blanketly deposited over the substrate 400. Contact plugs are formed in the inter-layer dielectric layer to connect source/drain regions in the substrate 400.

Due to the storage blocks common to the three described embodiments being defined by a first spacer thereon, a consistent width and channel length is achieved, providing smaller cell size. Further, the pair storage blocks defined by the first spacer instead of conventional lithography processes have substantially the same width. The reliability of the resultant devices is thus enhanced. Skip of one lithography process also results in lower manufacturing cost and simpler manufacturing processes.

On the other hand, the operating method of program, erase, and read for the memory cell of the third embodiment is a known art, and consequently details thereof are not described herein.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of thee appended claims should be accorded the broadest interpretation so as to encompass all such modifications and similar arrangements.

What is claimed is:

1. A self-aligned non-volatile memory, comprising:
a substrate;
two isolated storage blocks with substantially the same width overlying the substrate; and
a gate overlying the substrate and between the two storage blocks.

2. The self-aligned non-volatile memory as claimed in claim 1, wherein each of the storage blocks is polysilicon or silicon nitride.

3. The self-aligned non-volatile memory as claimed in claim 1, further comprising a tunneling dielectric layer interposed between the substrate and the storage blocks.

4. The self-aligned non-volatile memory as claimed in claim 1, further comprising a gate dielectric layer interposed between the substrate and the gate.

5. The self-aligned non-volatile memory as claimed in claim 1, further comprising:
an inter dielectric layer disposed on each of the storage blocks; and
a control gate disposed on the inter dielectric layer.

6. The self-aligned non-volatile memory as claimed in claim 5, wherein the gate functions as a select gate, and each of the isolated storage blocks function as a floating gate.

7. The self-aligned non-volatile memory as claimed in claim 5, further comprising a first spacer disposed on the control gate, and the width of each of the storage blocks is defined by the first spacer.

8. The self-aligned non-volatile memory as claimed in claim 5, further comprising a second spacer adjacent to a stack layer of each of the storage blocks, the inter dielectric layer and the control gate, wherein the stack layer and the gate are isolated by the second spacer.

9. The self-aligned non-volatile memory as claimed in claim 1, wherein the gate overlies the storage blocks.

10. The self-aligned non-volatile memory as claimed in claim 9, wherein the gate functions as a control gate and a select gate.

11. The self-aligned non-volatile memory as claimed in claim 9, further comprising an insulating layer interposed between the storage blocks and the gate.

12. The self-aligned non-volatile memory as claimed in claim 11, further comprising a spacer on each of the storage blocks, and the width of each of the storage blocks is defined by the spacer.

13. A self-aligned fabrication method for a non-volatile memory, comprising:
providing a substrate comprising a stacked layer formed thereon;
forming a sacrificial layer on the stacked layer;
patterning the sacrificial layer to form a first opening;
forming a first spacer on a sidewall of the first opening;
etching the stacked layer using the first spacer and the sacrificial layer as a first mask to form a second opening;
forming a conductive filling layer filling the first and the second openings; and
etching the stacked layer using the conductive filling layer as a second mask.

14. The method as claimed in claim 13, wherein the stacked layer comprises a floating gate layer, an inter dielectric layer, and a control gate layer;
the conductive filling layer functions as a select gate; and
a dielectric layer is disposed between the stacked layer and the substrate.

15. The method as claimed in claim 14, further comprising following steps prior to the step of forming the conductive filling layer:
forming an isolation layer in a portion of the first and the second openings; and
etching back the isolation layer to form a second spacer on a sidewall of the second opening.

16. The method as claimed in claim 15, wherein the substrate is exposed when etching back the isolation layer, and the method further comprises oxidizing the exposed substrate in the second opening to form a select gate dielectric layer.

17. The method as claimed in claim 14, wherein the floating gate layer is polysilicon or silicon nitride.

18. The method as claimed in claim 13, further comprising oxidizing the conductive filling layer to form a mask layer thereon, and etching the stacked layer is accomplished by using the mask layer and the conductive filling layer as a mask.

19. The method as claimed in claim 13, wherein the conductive filling layer comprises polysilicon.

20. The method as claimed in claim 13, wherein the stacked layer comprises a floating gate layer comprising polysilicon and a tunneling dielectric layer.

21. The method as claimed in claim 20, further comprising forming an isolation layer in a portion of the first and the second openings prior to the step of forming the conductive filling layer.

22. The method as claimed in claim 21, further comprising removing the first spacer prior to the step of forming the isolation layer.

23. The method as claimed in claim 22, wherein the floating gate layer and the substrate are exposed after removing the first spacer, and the forming of the isolation layer in the portion of the first and the second openings is accomplished by oxidizing the exposed floating gate layer and the exposed substrate.

24. The method as claimed in claim 13, wherein the stacked layer comprises a first oxide layer, a nitride layer on the first oxide layer and a second oxide layer on the nitride layer.

25. The method as claimed in claim 24, further comprising following steps prior to the step of forming the conductive filling layer:
removing the first spacer and the second oxide layer in the first opening; and
forming an isolation layer in a portion of the first and the second openings.

26. The method as claimed in claim 25, wherein the step of forming the isolation layer in the portion of the first and the second openings comprises depositing an oxide layer on the substrate and the sacrificial layer.

27. A self-aligned non-volatile memory structure, comprising a plurality of pair cells, a plurality of parallel gate lines, and a plurality of bit lines for connecting the pair cells, each of the pair cells comprising:
a gate electrode coupled to a corresponding gate line;
two storage blocks respectively disposed at opposing sides of the gate electrode; and
a first contact and a second contact adjacent to the two storage blocks respectively,
wherein a first and a second pair cells are controlled by one of the gate lines, and one of the bit lines connects the first contact of the first pair cells and the second contact of the second pair cells.

28. The structure as claimed in claim 27, wherein the first contact is a plug connecting a source/drain region of a substrate.

29. The structure as claimed in claim 27, wherein the bit lines are disposed in a zigzag pattern and extend substantially along a first direction not parallel to the gate lines.

30. The structure as claimed in claim 27, further comprising two control gate lines on opposite sides of each of the gate lines.

31. The structure as claimed in claim 30, wherein each of the pair cells further comprises two control gates disposed on the opposing sides of the gate electrode and coupled to the corresponding control gate lines.
